(19) United States
(12) Patent Application Publication
(10) Pub. No.: US 2007/0232074 A1
(43) Pub. Date: Oct. 4, 2007

(54) Techniques for the synthesis of dense, high-quality diamond films using a dual seeding approach

(76) Inventors: Kramadhati Ravi, Arherton, CA (US); Safak Sayan, San Jose, CA (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/394,751

(22) Filed: Mar. 31, 2006

(51) Int. Cl. H01L 21/31

(52) U.S. Cl. 438/758

(57) ABSTRACT

Embodiments of methods of forming a high thermal conductivity diamond film on a substrate using at least two different average particle sizes of diamond for nucleation and its associated structures.

### FIELD OF INVENTION

Integrated circuit structures.

### BACKGROUND OF INVENTION

One goal of microelectronic manufacturing is to increase the number of transistors on a device and thereby increase its operation speed. However, with increased transistor density and speed, power consumption is also increased dramatically. The heat generated from the increased power consumption can raise the microelectronic device temperature dramatically and degrade circuit performance and reliability. Therefore, reducing the overall device operation temperature is of great importance for optimum device performance.

Furthermore, operation of the transistors in a microelectronic device may cause non-uniform heating of the circuit. Certain points on the device may generate more heat than others, thus creating “hot spots”. Without such hot spots, it may be possible to increase the average power dissipation of the device while maintaining a desired temperature of the integrated circuit, thus allowing it to operate at a higher frequency.

In some applications, copper is bonded to a backside of a microelectronic device for dissipation of heat thereof. A typical problem associated with using copper to dissipate heat from microelectronic devices includes its low thermal conductivity value. In addition, because the copper is typically bonded to the backside of the device, the copper is not able to dissipate heat as quickly due to the distance between the copper and the transistors. Also, solder, a poor conductor of heat, is generally used to bond the copper to the backside surface of the microelectronic device

Another way to reduce hot spots is to form a layer of diamond on a device substrate, since the high thermal conductivity of diamond enables a diamond film to spread thermal energy laterally and thus greatly minimize the localized hot spots on the device. In general, methods for depositing a diamond film require “seeding”, or “nucleating”, the surface of a device substrate with very small diamond particles (approximately 0.25 micron (μm) in size). A layer of diamond is subsequently “grown” from the particles on the device substrate using known methods (i.e., chemical vapor deposition). Such layers generally have a small grain size which in turn can lead to a reduced thermal conductivity due to the high density of grain boundaries. “Grain boundaries” are the boundaries between individual nucleated seed particles. As the number of particles used in nucleation increases, the number of grain boundaries will increase. One approach to decreasing grain boundaries is to use larger sized diamond particles (approximately 3 to 5 μm in size) to nucleate the diamond film. However, since larger sized particles do not easily adhere to the device substrate, an embedding material may be used to embed the larger sized particles. A layer of diamond is subsequently “grown” from the particles on the device substrate using known methods (i.e., chemical vapor deposition). The resultant diamond film has a higher thermal conductivity due to decreased number of grain boundaries between the larger sized particles. However, due to the larger sized particles, this method can lead to voids in the diamond film at the diamond film-substrate interface.

Accordingly, there is a need for improved methods of diamond fabrication and structures formed thereby that increase the thermal conductivity of a diamond film and thereby improve its thermal management capabilities.

### BRIEF DESCRIPTION OF DRAWINGS

FIG. 1A shows a cross-sectional side view of a substrate.

FIG. 1B shows a cross-sectional side view of the substrate of FIG. 1A following the formation of a sacrificial layer thereon.

FIG. 1C shows a cross-sectional side view of the substrate of FIG. 1B following the deposition of a first population of diamond particles thereon.

FIG. 1D shows a cross-sectional side view of the substrate of FIG. 1C following the deposition of a second population of diamond particles thereon.

FIG. 1E shows a cross-sectional side view of the substrate of FIG. 1D during diamond growth thereon.

FIG. 1F shows a cross-sectional side view of the substrate of FIG. 1E after formation of a diamond film thereon.

FIG. 2A shows a cross-sectional side view of the substrate of FIG. 1F after formation of a polysilicon layer thereon.

FIG. 2B shows a cross-sectional side view of a second substrate subjected to hydrogen gas.

FIG. 2C shows a cross-sectional side view of a device layer of the second substrate of FIG. 2B in contact with the substrate of FIG. 2A.

FIG. 2D shows a cross-sectional side view of the substrate of FIG. 2C in which the device layer is exposed.

FIG. 3A illustrates heat dissipation of a diamond film.

FIG. 3B is a graph illustrating heat dissipation of a diamond film.

### DETAILED DESCRIPTION

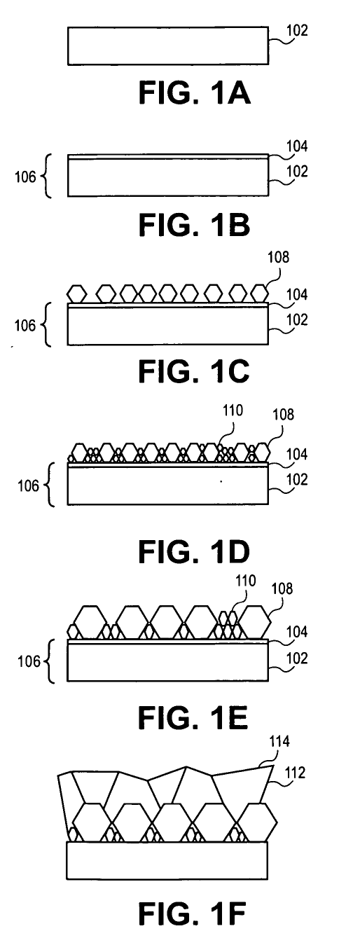

FIGS. 1A-1F illustrate one embodiment of forming a diamond film according to the present invention. In FIGS. 1A-1B, sacrificial layer 104 is coated on substrate 102 forming layer-coated substrate 106. Substrate 102 is a material such as silicon, silicon-on insulator, germanium, silicon-germanium, indium antimonide, lead telluride, indium arsenide, indium phosphide, gallium arsenide or gallium antimonide. Substrate 102 may be between 500 μm and 800 μm, for example, 775 μm.

In some embodiments, sacrificial layer 104 may be a photo-imaging material, such as a photoresist. Photoresists can be either negative or positive. In both forms, photoresists are three-component materials including a matrix, a photoactive compound and a solvent. For positive photoresists, the matrix may be a low-molecular weight novolac resin, the photoactive component may be a diazonaphthaquinone compound and the solvent system may be a mixture of n-butyl acetate, xylene and cellosolve acetate. For negative photoresists, the matrix may be cyclized synthetic rubber resin, the photoactive component may be a bis-arylazide compound and the solvent system may be an aromatic solvent. The photoresist material can be applied to substrate 102 by various methods, such as spinning. Sacrificial layer 104 may be in a thickness range of approximately 1 μm to 5 μm.

FIGS. 1C-1D illustrate one embodiment of depositing at least two different average particle sizes of diamond on sacrificial layer 104. In FIG. 1C-1D, first population 108 of diamond particles is deposited on layer-coated substrate 106 followed by second population 110 of diamond particles deposited thereon. In some applications, first population 108 may include diamond particles in the range of greater than 3 μm, for example, in a range between 3 μm and 20 μm. In some applications, second population 110 may include diamond particles in the range of less than 0.25 μm, for example, in a range between 0.05 μm and 0.25 μm. In some embodiments, second population 110 may be deposited before first population 108. It should be appreciated that more than two different average particle sizes of diamond particles may be used.

The deposition of first population 108 and second population 110, in any order, constitute seeding, or nucleating (hereinafter referred to interchangeably), of layer-coated substrate 106. Such seeding is necessary for “growing” a diamond film, representatively shown in FIG. 1E. Following the seeding of layer-coated substrate 106, heat may be applied thereto. The heat will cause first population 108 and second population 110 to at least partially embed into sacrificial layer 104. The temperature of the heat applied to layer-coated substrate 106 is in a range of approximately 200° C. to 300° C. where sacrificial layer 104 is photoresist.

Growing a diamond film tends to bow a substrate if that substrate has a thermal expansion coefficient higher than that of diamond. For example, the thermal expansion coefficient (alpha) of silicon is 3×10⁻⁶/° C., while the thermal expansion coefficient of diamond is 1×10⁻⁶/° C. In this case, applying a sacrificial layer, such as a photoresist material, will serve to cushion the silicon substrate as the diamond film is being nucleated thereon, thereby tending to reduce the stress level at the interface between the diamond film and the silicon substrate. In addition, larger diamond particle sizes used in seeding, e.g., particles greater than 3 μm, do not tend to adhere well to the substrate when deposited thereon. The photoresist material therefore serves as embedding material for larger diamond particle sizes for diamond growing. Moreover, applying a layer of photoresist leads to a more uniform dispersion of the seed particles when compared to conventional methods of surface preparation for diamond growing such as abrasion.

Rather than applying diamond particles and a sacrificial layer separately on a substrate, in some embodiments, first population 108, second population 110 or combined populations 108 and 110 may be combined with photoresist to create a mixture. The concentration or dispersion of the particles can be in a range from approximately 10² to 10³ particles/cm². The mixture can be applied directly to substrate 102 by a photoresist spinning method for diamond growing thereof.

Layer-coated substrate 106 with embedded particles can be subjected to a diamond deposition process. Such processes include, but are not limited to, physical vapor deposition (PVD), atomic layer deposition (ALD), chemical vapor deposition (CVD), low pressure CVD, plasma-enhanced CVD or any other suitable process. Such processes are known by those skilled in the art. In one embodiment, CVD deposition is used. A mixture of a hydrocarbon, such as methane, and hydrogen can be used at a temperature in the range of 700° C. to 900° C. for formation of the diamond film. During CVD, sacrificial layer 104, e.g., a photoresist material, can be “ashed” away, or removed due to the high temperature. The result is a dense, large grain size polycrystalline diamond film 112 (see FIG. 1F). In some embodiments, the diamond film 112 is in the range of approximately 20 μm to 30 μm.

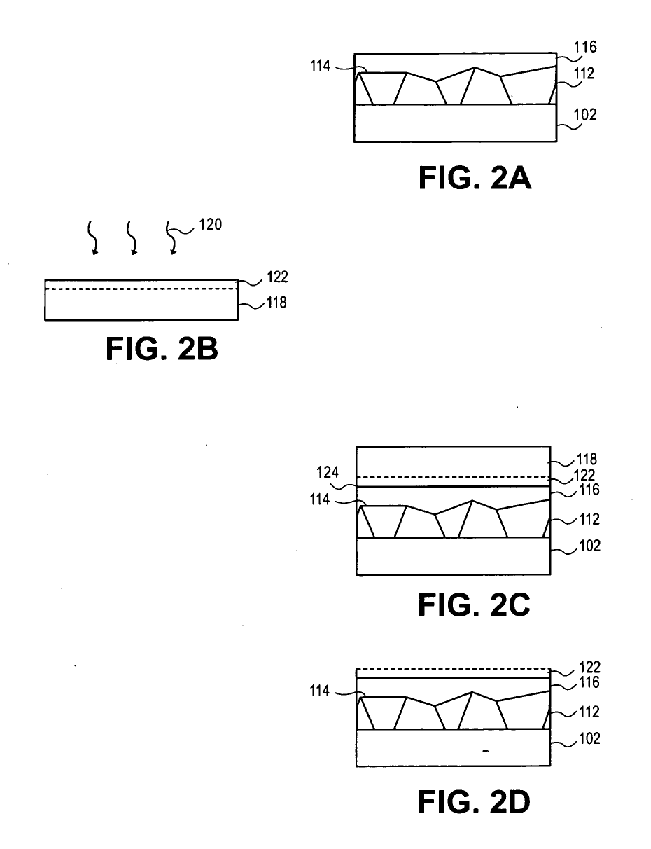

After the formation of the diamond film 112 (e.g., by growing from a seed layer(s) of first population 108 and second population 110), the uppermost surface 114 remains rough. In order to form transistors thereon, the surface of the substrate 102 must have a high purity layer of semiconducting material. In some embodiments, a layer of polysilicon 116 may be deposited on surface 114 (see FIG. 2A). The deposition of polysilicon layer 116 may then be formed by such processes as PVD, ALD, CVD, low pressure CVD, plasma-enhanced CVD or any other suitable process. Layer 116 may then be planarized by, for example, chemical mechanical polishing. Layer 116 may be deposited to a thickness suitable to allow the formation of a planar layer of polysilicon on diamond film 112. Once deposited, layer 116 can be in a range from approximately 10 μm to 15 μm.

A secondary substrate 118 may then be subjected to hydrogen gas (arrows 120) to form a weakened layer and a device layer 122 (see FIG. 2B). Secondary substrate 118 is, for example, a silicon substrate (e.g., a single crystal silicon substrate). After treatment with hydrogen gas, secondary substrate 118 may be “flipped” onto polysilicon layer 116 to form an interface 124 between device layer 122 and polysilicon layer 116. Secondary substrate 118 may then be broken off at interface 124 between device layer 122 and substrate 118 resulting in an exposed device layer 122 (see FIG. 2D). Device layer 122 is generally from 2 μm to 3 μm. In some embodiments, the resulting structure is a microelectronic device.

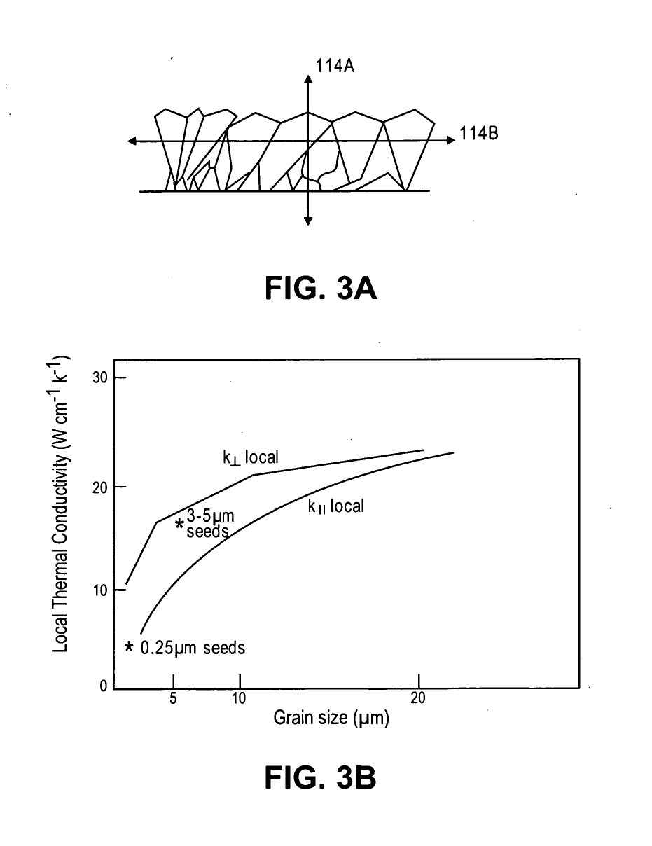

When a microelectronic device is heated during processing operations, heat will dissipate in both a parallel and perpendicular direction with respect to the substrate. Seed particle size affects heat dissipation. Heat dissipation is representatively shown in FIG. 3A. Heat dissipation in the parallel direction is represented by arrow 114A while heat dissipation in the perpendicular direction is represented by arrow 114B (see FIG. 3A). Depending on a number of factors, heat dissipation in the perpendicular direction is generally greater than in the parallel direction. However, the heat dissipation in the parallel direction (k_{∥}) approaches the heat dissipation in the perpendicular direction (k_{⊥}) as the grain size of the particles increases in diamond deposition (see FIG. 3B).

Other factors which affect heat dissipation include the number of grain boundaries and voids. As the number of particles used in nucleation increases, the number of grain boundaries will increase. Thus, using only small grain particles (0.05 μm to 0.25 μm), which necessarily means a greater number of particles required to be dispersed on the substrate, will result in a substantial number of grain boundaries. A substantial number of grain boundaries decreases heat dissipation in the parallel direction because the heat has to “jump” between the boundaries of each particle which has been nucleated as it travels in the parallel and/or perpendicular direction. On the other hand, using only large grain particles (3 μm to 20 μm) will result in a reduced number of grain boundaries, but will additionally result in a substantial number of voids between the particles due to their larger irregular sizes. When dispersed on a substrate, large grain particles will not be able to pack together as tightly when compared to small grain particles, leaving voids in between. Heat dissipation in both the parallel and perpendicular directions will be reduced due to voids.

As a result of the above-described embodiment of a method of diamond deposition in accordance with the present invention, the number of grain boundaries and voids are substantially reduced. That is, the increase in grain size and density of the diamond film results in a more uniform and consistent diamond film with enhanced thermal conductivity. Diamond film 112 has a thermal conductivity between 895 and 2300 W/mK, with greater than 1000 W/mK preferred. Accordingly, for increased speed during operating processes, more transistors can be placed on a microelectronic device which can accordingly tolerate more heat. It is anticipated that microelectric devices manufactured according to embodiments of the present invention will result in operating speeds between 2 GHz and 3 GHz.

As described above, embodiments of the present invention provide methods and structures formed thereby of nucleating a substrate by depositing at least two different average particle sizes of diamond in order to promote the growth of diamond films. The resulting increase in thermal conductivity of the diamond film greatly improves the ability of a diamond film to thermally manage a microelectronic device, such as in the thermal management of hot spots across a device. Specifically, the methods disclosed herein increase diamond seed particle dispersion and correspondingly reduce voids, improve adhesion of the particles due to increased dispersion during seeding, enable stress reduction and increase parallel heat dissipation. Moreover, diamond depositions according to the methods herein disclosed will be subject to multiple-stage temperature growth per the Gibbs-Thompson theorem. Thus, the reliability and speed of a microelectronic device are greatly enhanced.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that the fabrication of a multiple metal layer structure atop a substrate, such as a silicon substrate, to manufacture a silicon device is well known in the art. Therefore, it is appreciated that the figures provided herein illustrate only portions of an exemplary microelectronic device that pertains to the practice of the present invention. Thus the present invention is not limited to the structures described herein.

What is claimed is:

1. A method, comprising:
forming a layer of sacrificial material on a substrate;
depositing a first layer of diamond particles on the sacrificial material;
depositing a second layer of diamond particles on the sacrificial material; and
after the depositing, forming a diamond film using at least one of the particles of the first layer and the particles of the second layer as a nucleation site.

2. The method of claim 1, wherein the substrate is a silicon wafer.

3. The method of claim 1, wherein (a) the first layer of diamond particles consists of particles greater than 3 microns and (b) the second layer of diamond particles consists of particles less than 0.25 microns.

4. The method of claim 1, wherein the sacrificial material is photoresist.

5. The method of claim 4, further comprising, after the depositing, heating the photoresist to a temperature sufficient to embed at least one of the particles in the photoresist.

6. The method of claim 1 further comprising, after forming the diamond film, forming a device layer of semiconductor material.

7. The method of claim 6 further comprising, prior to forming the device layer, forming a planarizing layer such that the planarizing layer is between the diamond layer and the device layer.

8. A method comprising:
forming a photoresist layer on a device wafer;
forming a nucleation layer of diamond particles comprising at least two different average particle sizes; and
forming a diamond film from the nucleation layer.

9. The method of claim 8, wherein at least one average particle size is less than 0.25 microns and at least one average particle size is greater than 3 microns.

10. The method of claim 8 further comprising, after the depositing, heating the photoresist to a temperature sufficient to embed at least one of the particles in the photoresist.

11. The method of claim 8 further comprising, after forming the diamond film, forming a device layer of semiconductor material.

12. The method of claim 11 further comprising, prior to forming the device layer, forming a planarizing layer such that the planarizing layer is between the diamond layer and the device layer.

13. A composition comprising:
a photo-imaging material; and
one of (a) at least one first diamond particle of a first average particle size and (b) at least one second diamond particle of a second average particle size.

14. The composition of claim 13, wherein the photo-imaging material is a photoresist.

15. The composition of claim 14, wherein the photoresist is negative or positive photoresist.

16. The composition of claim 14, wherein the photoresist comprises at least one of a matrix, a photoactive compound and a solvent system.

17. A method comprising:
forming a nucleation layer on a device wafer, wherein the layer comprises a composition comprising (a) a photo-imaging material and (b) one of (i) at least one first diamond particle of a first average particle size and (ii) at least one second diamond particle of a second average particle size; and
forming a diamond film from the nucleation layer.

18. The method of claim 17, wherein at least one average particle size is less than 0.25 microns and at least one average particle size is greater than 3 microns.

19. The method of claim 17 further comprising, after forming the diamond film, forming a device layer of semiconductor material.

20. The method of claim 19 further comprising, prior to forming the device layer, forming a planarizing layer such that the planarizing layer is between the diamond layer and the device layer.
